(19) United States
(12) Patent Application Publication
(10) Pub. No.: US 2014/0264917 A1
(43) Pub. Date: Sep. 18, 2014

(54) A Semiconductor Device with a Through-Silicon Via and a Method for Making the Same

(71) Applicant: IPEnval Consultant Inc., Hsinchu City (TW)

(72) Inventors: Chao-Yuan Huang, Hsinchu City (TW); Yueh-Feng Ho, Hsinchu City (TW); Ming-Sheng Yang, Hsinchu City (TW); Hwi-Huang Chen, Hsinchu City (TW)

(73) Assignee: IPEnval Consultant Inc., Hsinchu City (TW)

(21) Appl. No.: 13/834,061

(22) Filed: Mar. 15, 2013

(51) Int. Cl. H01L 23/498; H01L 21/768

(52) U.S. Cl. CPC H01L 23/49827; H01L 21/76879
USPC 257/774; 438/667

(57) ABSTRACT

A semiconductor device with a through-silicon via comprises a substrate with a front side and a backside and a through-silicon via penetrating the substrate with a circular shape on the front side and a corner-rounded rectangular shape on the back side.

### FIELD OF THE INVENTION

The present invention relates to a semiconductor device with a through-silicon via and a method for making the same.

### BACKGROUND OF THE INVENTION

To save precious layout space or increase interconnection efficiency, multiple chips of integrated circuits (ICs) can be stacked together as a single IC package. To that end, a three-dimensional (3D) stack packaging technology is used to package the chips of integrated circuits. Through-silicon vias (TSVs) are widely used to accomplish the 3D stack packaging technology. A through-silicon via is a vertical conductive via completely passing through a silicon wafer, a silicon board, a substrate of any material or die. Nowadays, a 3D integrated circuit (3D IC) is applied to a lot of fields such as memory stacks, image sensors or the like.

Although through-silicon vias comes with a lot of advantages, the manufacturing process for them are quite new to this industry. There are still room for new structures and/or novel manufacturing processes.

### SUMMARY OF THE INVENTION

In one embodiment of the present invention, a semiconductor device with a through-silicon via is provided to comprise a substrate with a front side and a backside and a through-silicon via penetrating the substrate with a circular shape on the front side and a corner-rounded rectangular shape on the back side.

In another embodiment of the present invention, a method for manufacturing a semiconductor device is provided to comprise the following steps. Provide a substrate with a first side and a second side. Form a through silicon hole in the substrate from the first side. Form a protective layer on the sidewall of the through silicon hole while exposing the bottom of the through silicon hole. Enlarge the bottom and modifying the shape of the bottom of the through silicon hole. Form a dielectric layer lining the sidewall and bottom of the through silicon hole. Form a conductive material filling the through silicon hole. Remove a portion of the substrate from the second side to exposed the conductive material and complete a through silicon via.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 shows a schematic cross-sectional view of a semiconductor device with a through-silicon via (TSV) in accordance with an embodiment of the present invention;

FIG. 1A shows a schematic top view of the front side of the TSV of FIG. 1 in accordance with an embodiment of the present invention;

FIG. 1B shows a schematic top view of the backside of the TSV of FIG. 1 in accordance with an embodiment of the present invention;

FIGS. 2-7 show a manufacturing method of the semiconductor device with the TSV in accordance with an embodiment of the present invention.

### DETAILED DESCRIPTION OF PREFERRED EMBODIMENTS

The following is the detailed description of the preferred embodiments of this invention. All the elements, sub-elements, structures, materials, arrangements recited herein can be combined in any way and in any order into new embodiments, and these new embodiments should fall in the scope of this invention defined by the appended claims. A person skilled in the art, upon reading this invention, should be able to modify and change the elements, sub-elements, structures, materials, arrangements recited herein without being apart from the principle and spirit of this invention. Therefore, these modifications and changes should fall in the scope of this invention defined only by the following claims.

There are a lot of embodiments and figures in this application. To avoid confusions, similar components are represented by same or similar numerals. To avoid complexity and confusions, only one of the repetitive components is marked. Figures are meant to deliver the principle and spirits of this invention, so the distance, size, ratio, shape, connection relationship, etc. are examples instead of realities. Other distance, size, ratio, shape, connection relationship, etc. capable of achieving the same functions or results can be adopted as equivalents.

Now refer to FIG. 1, which shows a schematic cross-sectional view of a semiconductor device with a through-silicon via (TSV) 1000 in accordance with an embodiment of the present invention. In the present invention, the focus is on the TSV not on what's above or around the TSV, so the active devices around TSV and interconnects above TSVs are omitted to keep the figures plain and simple. The TSV 1000 (in some references also known as through electrode, conductive post . . . etc.) passes “through” a substrate 100 and physically and electrically connect the backside 102 and front side 101 of substrate 100. The TSV 1000 is configured to couple operation voltage VSS, VDD or operational signal to the integrated circuits (not shown) formed on the substrate 100, or configured to transfer signals and/or voltages between chips. Compared to normal active devices such as transistors, TSV 1000 has a much bigger size in a scale of micrometers. In one embodiment, TSV 1000 has a diameter of about 30 μm while it has a circular shape. In another embodiment, TSV 1000 has a diameter of about 10 μm while it has a circular shape. In a further embodiment, TSV 1000 has a diameter equivalent to or larger than 1 μm such as about 5 μm while it has a circular shape.

The TSV 1000 shown in FIG. 2-5 seems to be a TSV made from a via middle or via first process, however TSV 1000 may be made from a via first process (via is made before transistors), a via middle process (via is made after transistors and during lower interconnects) or a via last process (via is made after interconnects). No matter what kind of process is adopted to fabricate TSV 1000, the basic structure of TSV 1000 is the same: a through-silicon hole 150/150′ (not shown in FIG. 1 but shown in FIG. 2-4), a dielectric layer 152′ lining on the wall of the through-silicon hole, and a conductive material 900′ filled in the through-silicon hole. The material/materials used for the dielectric layer 152′ and the conductive material 900′ may depend on the manufacturing process and the physical properties needed. Silicon oxide and/or silicon nitride are the most commonly used material/materials for the dielectric layer 152′. As to the conductive material 900′, it may comprise a barrier/glue layer material such as Ta, TaN, Ti, TiN, W, WN, Mo, Mn, Cu and a low-resistivity material such as W, Cu, Al, poly silicon.

On the front side 101 above the TSV 1000 is a device/interconnect layer 500. Device/interconnect layer 500 represents all the optional active devices, inter-layer dielectric layer and contacts (if TSV 1000 is made by via first process) and inter-metal dielectric layers and all the interconnect structures embedded within. It should be understood, FIG. 1-6 only show a part of a complete picture, therefore the substrate 100 may comprise shallow trench isolation structure, passive devices such as resistors, every kinds of doped regions, dummy patterns and optional active devices (if TSV 1000 is made by via middle process). At the front side the TSV 1000 configured to couple to interconnect structures (not shown) has a circular shape with diameter of d as shown in FIG. 1A. The diameter d is equivalent to or larger than 1 μm such as about 5 μm. At the backside the TSV 1000 configured to couple to backside redistribution line (RDL) 600 for backside routing has a corner-rounded rectangular shape with a long edge-length of D as shown in FIG. 1B. The long edge-length D is at least 1.2 times larger than the diameter d, so long edge-length D is at least equivalent to or larger than 1.2 μm such as about 6 μm. The function of RDL 600 can be understood as connections between TSV 1000 and other TSVs (not shown) and/or connections between TSV 1000 and micro bump/bump 700, so RDL 600 is similar to interconnect structures on the front side and may come with several layers disposed along a vertical direction within one or more dielectric/isolation layers. The micro bump/bump 700 is an internal interface allowing TSVs (hence active devices) to communicate with outside.

Now refer to FIGS. 1A and 1B, which show schematic top views of the front side and back side of the TSV of FIG. 1 in accordance with an embodiment of the present invention. From FIGS. 1A and 1B it is clear that the long-edge length D of the corner-rounded rectangular shape is larger than the diameter d of the circular shape. FIG. 1B not only shows TSV 1000 but also shows the RDL 600 overlapping with TSV 1000. In order to improve the contact between TSV 1000 and RDL 600, the long-edge of TSV 1000 at backside should be parallel to the long-edge (length) direction of RDL 600 as shown in FIG. 1B.

It should be understood, the principles of the present invention can also be applied to a Si interposer. In that case, FIG. 1A would represent a portion of a TSV buried within the substrate 100, FIG. 1B would represent two ends exposed from the front side and backside of the substrate 100 and the device/interconnect layer 500 would be replaced by one or more RDLs and micro bumps/bumps.

Now refer to FIGS. 2-7, which show a manufacturing method of the semiconductor device with the TSV in accordance with an embodiment of the present invention. In FIG. 2, a substrate 100 is provided and a through-silicon hole 150 is formed within the substrate 100 from the front side 101 without penetrating the whole substrate 100. Then, a dielectric layer 151 is formed lining the sidewall and bottom of the through-silicon hole 150. The substrate 100 may be a simple silicon substrate or a silicon on insulator substrate, or substrate 100 may comprise shallow trench isolation structures, passive devices such as resistors, every kinds of doped regions, dummy patterns and optional active devices (if TSV 1000 is made by via middle process). The through-silicon hole 150 can be formed by photolithography and etching processes. The dielectric layer 151 can be formed by thermal oxidation so only be formed on the exposed silicon surface or it can be formed by deposition process covering the entire front surface of the substrate 100 and sidewall and bottom of the through-silicon hole 150. The dielectric layer 151 may comprise the most commonly used dielectric materials silicon oxide and/or silicon nitride.

In FIG. 3, an anisotropic etching is performed to remove a portion of the dielectric layer 151 on the substrate surface and a portion of the dielectric layer 151 on the bottom of the through-silicon hole 150, so a ring-shaped dielectric layer 151′ is obtained as a protective layer to expose the bottom but protect the sidewall of the through-silicon hole 150.

In FIG. 4, a wet etching is performed to enlarge/deepen and modify the shape of the bottom of the through-silicon hole 150, so a modified through-silicon hole 150′ is obtained. It is noted that since the substrate surface is also exposed, when the substrate surface has silicon exposed, an optional protective mask (not shown) may be formed on the substrate surface in order to keep the substrate surface intact during the wet etching. When the substrate surface is a dielectric surface and has no silicon exposed, no protective mask is needed. The chemicals used for wet etching may comprise tetramethylammonium hydroxide (TMAH) or ammonia. Because etching rates for different crystal planes are different, the enlarged and modified bottom of the modified through-silicon hole 150′ has a corner-rounded rectangle shape.

In FIG. 5, the optional protective mask is removed and another dielectric layer (not shown) is formed lining on the substrate surface and the sidewall and bottom of the modified through-silicon hole 150′. The old dielectric layer 151′ and the newly formed dielectric layer (not shown) would merge together to become dielectric layer 152. Then, a conductive material (not shown) is formed filling the modified through-silicon hole 150′ and a chemical mechanical polishing process is performed to remove the excess conductive material and form a global flat surface, thereby forming conductive material 900. The conductive material 900 may comprise a barrier/glue layer material such as Ta, TaN, Ti, TiN, W, WN, Mo, Mn, Cu and a low-resistivity material such as W, Cu, Al, poly silicon.

In FIG. 6, a device/interconnect layer 500 is formed on top of the conductive material 900 and the substrate surface. The device/interconnect layer 500 represents all the optional active devices, inter-layer dielectric layer and contacts (if TSV 1000 is made by via first process) and inter-metal dielectric layers and all the interconnect structures embedded within.

In FIG. 7, a backside grinding/polishing/thinning is performed in order to expose the conductive material and complete the TSV 1000 comprising a dielectric layer 152′ and a conductive material 900′.

Finally, a patterned dielectric layer (not shown) is formed on the backside 102 in order to electrically isolate different RDLs and RDL 600 and micro bump/bump 700 are formed on the TSV 1000.

In this way, the present invention can provide better contact between TSVs and RDLs. It is also noted that the manufacturing process demonstrated by FIGS. 2-7 are only exemplary and the present invention is not limited thereto. Other manufacturing methods capable of achieving the same TSV structure as shown in FIGS. 1, 1A and 1B would fall within the scope of the present invention.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A semiconductor device with a through-silicon via, comprising:
a substrate with a front side and a backside; and
a through-silicon via penetrating the substrate with a circular shape on the front side and a corner-rounded rectangular shape on the back side.

2. The semiconductor device with a through-silicon via of claim 1, further comprising a device/interconnect layer on the front side.

3. The semiconductor device with a through-silicon via of claim 1, wherein the long-edge length of the corner-rounded rectangular shape is larger than the diameter of the circular shape.

4. The semiconductor device with a through-silicon via of claim 1, wherein the long-edge length of the corner-rounded rectangular shape is at least 1.2 times larger than the diameter of the circular shape.

5. The semiconductor device with a through-silicon via of claim 1, further comprising a backside redistribution line (RDL) on the backside.

6. The semiconductor device with a through-silicon via of claim 5, wherein the long-edge length of the corner-rounded rectangular shape is parallel to the length direction of the backside redistribution line (RDL).

7. The semiconductor device with a through-silicon via of claim 1, wherein the semiconductor device is configured to be a Si interposer.

8. A method for manufacturing a semiconductor device, comprising:
providing a substrate with a first side and a second side;
forming a through silicon hole in the substrate from the first side;
forming a protective layer on the sidewall of the through silicon hole while exposing the bottom of the through silicon hole;
enlarging the bottom and modifying the shape of the bottom of the through silicon hole;
forming a dielectric layer lining the sidewall and bottom of the through silicon hole;
forming a conductive material filling the through silicon hole; and
removing a portion of the substrate from the second side to exposed the conductive material and complete a through silicon via.

9. The method for manufacturing a semiconductor device of claim 8, wherein the first side and the second side are the front side and backside respectively.

10. The method for manufacturing a semiconductor device of claim 8, wherein the through silicon hole has a circular shape with the diameter equivalent to or larger than 1 μm on the first side.

11. The method for manufacturing a semiconductor device of claim 8, wherein the through silicon hole has a corner-rounded rectangular shape with the long-edge length equivalent to or larger than 1.2 μm on the second side.

12. The method for manufacturing a semiconductor device of claim 8, wherein the protective layer on the sidewall is a dielectric layer.

13. The method for manufacturing a semiconductor device of claim 8, wherein forming the protective layer on the sidewall of the through silicon hole while exposing the bottom of the through silicon hole comprises:
forming a dielectric layer on the sidewall and on the bottom of the through silicon hole; and
removing a portion of the dielectric layer on the substrate and on the bottom of the through silicon hole.

14. The method for manufacturing a semiconductor device of claim 8, wherein enlarging the bottom and modifying the shape of the bottom of the through silicon hole comprises:
performing a wet etching process to enlarge and deepen the through silicon hole and modify the shape of the bottom of the through silicon hole.

15. The method for manufacturing a semiconductor device of claim 14, wherein the wet etching process uses tetramethylammonium hydroxide (TMAH) or ammonia.

16. The method for manufacturing a semiconductor device of claim 8, wherein forming a dielectric layer on the sidewall and on the bottom of the through silicon hole comprises:
performing a thermal oxidation process.

17. The method for manufacturing a semiconductor device of claim 8, wherein forming a dielectric layer on the sidewall and on the bottom of the through silicon hole comprises:
performing a deposition process.

18. The method for manufacturing a semiconductor device of claim 8, wherein forming a conductive material filling the through silicon hole comprises:
forming a barrier/glue layer material; and
forming a low-resistivity conductive material.

19. The method for manufacturing a semiconductor device of claim 18, wherein the barrier/glue layer material comprises Ta, TaN, Ti, TiN, W, WN, Mo, Mn and/or Cu.

20. The method for manufacturing a semiconductor device of claim 18, wherein the low-resistivity conductive material comprises W, Cu, Al and/or poly silicon.
